(19) United States
(12) Patent Application Publication
(10) Pub. No.: US 2013/0020632 A1
(43) Pub. Date: Jan. 24, 2013

(54) LATERAL TRANSISTOR WITH CAPACITIVELY DEPLETED DRIFT REGION

(71) Applicant: Donald R. Disney, Cupertino, CA (US)

(72) Inventor: Donald R. Disney, Cupertino, CA (US)

(21) Appl. No.: 13/185,402

(22) Filed: Jul. 18, 2011

(51) Int. Cl. H01L 29/772; H01L 21/336

(52) U.S. Cl. 257/328; 438/286; 257/335; 257/E29.242; 257/E21.409

(57) ABSTRACT

A lateral transistor includes a gate formed over a gate oxide and a field plate formed over a thick gate oxide. The field plate is electrically connected to a source. The field plate is configured to capacitively deplete a drift region when the lateral transistor is in the OFF state.

### BACKGROUND OF THE INVENTION

1. Field of the Invention

The present invention relates generally to electrical devices, and more particularly but not exclusively to metal-oxide semiconductor (MOS) transistors.

2. Description of the Background Art

Lateral transistors, such as lateral double diffused metal-oxide semiconductor (DMOS) transistors, are employed in a wide variety of electrical applications including as switching elements in voltage regulators. A lateral DMOS transistor may include a gate overlying a gate dielectric, the gate dielectric having a thin portion over a channel region and part of a drift region, and a thick portion over an additional part of the drift region. The thin portion is simply referred to as a “gate oxide”, while the thick portion is referred to as a “thick gate oxide.” A continuous gate is formed over the entire surface of the gate dielectric, including over at least a portion of the thick gate oxide. The thick gate oxide reduces electric field in the gate region, advantageously increasing the breakdown voltage of the transistor. This configuration, however, increases drain-to-gate capacitance, adversely impacting the switching speed of the transistor.

### SUMMARY

In one embodiment, a lateral transistor comprises an epitaxial layer formed over a substrate. The transistor further comprises a source, a drain, and a gate dielectric having a gate oxide and a thick gate oxide, the thick gate oxide being thicker than the gate oxide, the gate dielectric being formed over the epitaxial layer. The gate oxide and the thick gate are formed between the source and the drain. A gate is formed over the gate oxide and a field plate is formed over the thick gate oxide but not over the gate oxide. An interlayer dielectric has a first via to the source and a second via to the field plate. A source electrode electrically connects the source to the field plate by way of the first and second vias through the interlayer dielectric.

In another embodiment, a method of fabricating a lateral transistor comprises forming a gate oxide and a thick gate oxide over an epitaxial layer, the thick gate oxide being thicker than the gate oxide, forming a gate material over the gate oxide and the thick gate oxide, patterning the gate material into two separate portions comprising a gate over the gate oxide and a field plate over the thick gate oxide, the gate and the field plate being physically separated by a gap, and electrically connecting the field plate to a source.

In another embodiment, a lateral transistor comprises a P-type semiconductor layer, a gate formed over a gate oxide, and a field plate formed over a thick gate oxide but not over the gate oxide, the thick gate oxide being thicker than the gate oxide. An N+ source is formed in a P body region and an N+ drain is formed in a drift region. A gap separates the gate and the field plate.

These and other features of the present invention will be readily apparent to persons of ordinary skill in the art upon reading the entirety of this disclosure, which includes the accompanying drawings and claims.

### DESCRIPTION OF THE DRAWINGS

FIG. 1 shows a cross-section of a lateral transistor in accordance with an embodiment of the present invention.

FIG. 2 shows a flow diagram of a method of fabricating a lateral transistor in accordance with an embodiment of the present invention.

FIGS. 3-5 show cross-sections schematically illustrating formation of a gate oxide and a thick gate oxide in accordance with an embodiment of the present invention.

FIG. 6 shows a larger view of the gate and field plate of the transistor of FIG. 1, illustrating example dimensions in accordance with an embodiment of the present invention.

FIG. 7 shows a lateral transistor in accordance with an embodiment of the present invention.

FIG. 8 shows a lateral transistor in accordance with an embodiment of the present invention.

The use of the same reference label in different drawings indicates the same or like components. The drawings are not to scale.

### DETAILED DESCRIPTION

In the present disclosure, numerous specific details are provided, such as examples of structures and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

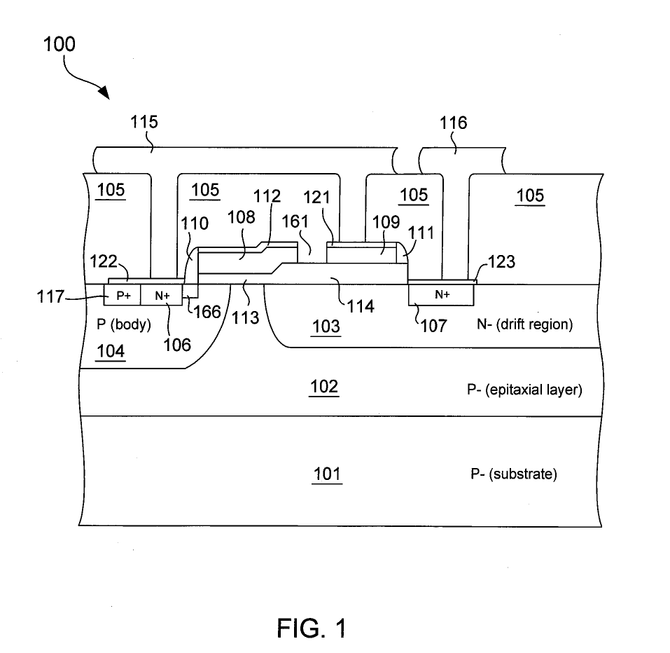

FIG. 1 shows a cross-section of a lateral transistor in the form of a lateral DMOS transistor 100 in accordance with an embodiment of the present invention. In the example of FIG. 1, the transistor 100 comprises a P− (i.e., lightly doped with a P-type dopant) epitaxial layer 102 formed over a P-type substrate 101. The substrate 101 may comprise a silicon wafer. The epitaxial layer 102 may be about 3-6 μm thick, while the substrate 101 may be about 200-600 μm thick. FIG. 1 and all other drawings in this disclosure are not drawn to scale for clarity and ease of illustration. Also, the epitaxial layer 102 and the substrate 101 may be doped with an N-type dopant, with appropriate changes to the doping of other features of the transistor 100.

In the example of FIG. 1, a P-type body region 104 and an N-type drift region 103 are formed in the epitaxial layer 102. The body region 104 may be separated from the drift region 103 by a portion of the P-type epitaxial layer 102, as shown. In other embodiments, the P-type body region 104 and the N-type drift region 103 may be touching or even overlapping. In the example of FIG. 1, neither the body region 104 nor the drift region 103 extends to the substrate 101. In other embodiments, either or both of the body region 104 and/or drift region 103 may extend vertically to contact or overlap with the substrate 101.

Also formed in the epitaxial layer 102 are a P+ (i.e., heavily doped with a P-type dopant) contact region 117, an N+ (i.e., heavily doped with an N-type dopant) source 106, an N− lightly doped source (LDS) region 166, and an N+ drain 107. The contact region 117 enhances electrical connection to the body region 104. In the example of FIG. 1, the source 106 is formed in the body region 104 and the drain 107 is formed in the drift region 103.

In the example of FIG. 1, the transistor 100 comprises a gate dielectric having a thin portion (see 113) and a thick portion (see 114). The gate dielectric may comprise grown or deposited silicon dioxide. The thin portion is referred to simply as the “gate oxide 113” and the thick portion 114 is referred to as a “thick gate oxide 114”. The gate oxide 113 is formed over the body region 104 and over a portion of the epitaxial layer 102 between the body region 104 and the drift region 103, i.e., in regions where a channel is formed in the ON state (i.e., when the transistor 100 is switched ON). A relatively small portion of the gate oxide 113 also extends over the drift region 103 such that the channel makes good electrical contact with the drift region. The thick gate oxide 114 is formed over at least a portion of the drift region 103.

A gate 108, which may comprise polysilicon, is formed on the gate oxide 113, and in some embodiments extends onto a portion of the thick gate oxide 114. A field plate 109, which may comprise the same material as the gate 108, is formed on the thick gate oxide 114 and functions to capacitively deplete the drift region 103 in the OFF state (i.e., when the transistor 100 is switched OFF). In some embodiments, silicide layers 112 and 121 are formed on the gate 108 and field plate 109, respectively. Source electrode 115 electrically connects the field plate 109 to the source 106. A source electrode 115 may comprise a metal layer. The source electrode 115 electrically connects to the field plate 109 by way of the silicide layer 121 and to the source 106 by way of a silicide layer 122. A drain electrode 116, which may comprise the same metal as the source electrode 115, electrically connects to the drain 107 by way of a silicide layer 123.

The field plate 109 is not electrically connected to the drain 107 or to the gate 108. The field plate 109, the drain 107, and the gate 108 are electrically isolated from each other by portions of the interlevel dielectric (ILD) 105. The field plate 109, the thick gate oxide 114, and the drift region 103 form a metal-oxide-semiconductor (MOS) capacitor configured to capacitively deplete charge from the drift region 103. When the transistor 100 is in the OFF-state, field plate 109 capacitively depletes free carriers from the drift region 103. This provides two benefits. First, the drift region 103 can contain more N-type charge without degrading the breakdown voltage of the transistor 100 than would be possible without the capacitive depletion. More charge in the drift region 103 results in lower ON-state resistance for the transistor 100. Second, the capacitive depletion of the drift region 103 by the source-connected field plate 109 lowers the electric field between the gate 108 and the drift region 103 (i.e., the field plate 109 shields the gate 108 from high electric fields), thereby improving the breakdown voltage of the transistor 100.

Conventional lateral DMOS transistors get a similar capacitive depletion and shielding effect by extending the gate laterally over the thick gate oxide, essentially forming a gate-connected field plate. However, this gate-connected field plate greatly increases the gate-drain capacitance of the lateral DMOS transistor. The present embodiments achieve the benefits of capacitive depletion and shielding effect, while the gate-drain capacitance is minimized.

A gate electrode (not shown) electrically connects to the gate 108, such as along a direction perpendicular to the page of FIG. 1. Sidewall spacers 110 and 111 allow for ease of fabrication by facilitating alignment of implantation steps. For example, the lightly doped source 166 may be self-aligned to the gate 108 while the source 106 may be self-aligned to the spacer 110. The drain 107 may be self-aligned to the spacer 111. In other embodiments, the drain 107 may be spaced laterally away from the spacer 111 by a photomasking step in order to form a longer drift region.

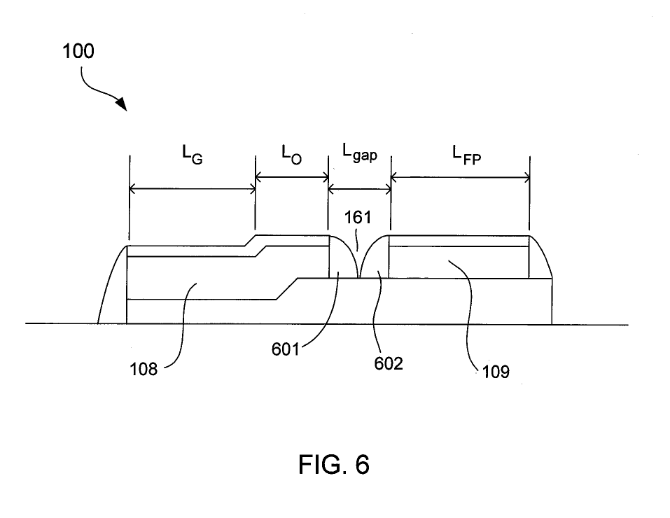

In the example of FIG. 1, the gate 108 is formed on the gate oxide 113 and on a portion of the thick gate oxide 114. As a particular example, in a transistor 100 having a breakdown voltage of about 25 V, the length of the gate 108 (see L_{G} in FIG. 6) may be about 0.3 μm over the gate oxide 113 and may extend about 0.1 μm over the thick gate oxide 114 (see L_{O} in FIG. 6). A gap 161 physically and electrically separates the gate 108 from the field plate 109. Preferably, the gap 161 is narrow enough such that when the transistor 100 is OFF, the field plate 109 above the thick gate oxide 114 is close enough to the gate 108 such that it reduces electrical field at the edge of the gate 108, thereby improving breakdown voltage. However, the gap 161 should be wide enough to prevent substantial degradation of the portion of the ILD 105 in this gap under the presence of the maximum potential difference between the gate 108 and the field plate 109. In the example transistor 100 with a breakdown voltage of 25 V, the gap 161 may be about 0.1-0.2 μm, for example. The gap 161 may be filled with sidewall spacers comprising a dielectric (e.g., spacers 601 and 602 in FIG. 6).

For ease of fabrication, the field plate 109 and the gate 108 may be formed in a same deposition step and then separated by etching. In that example, the length of the gap 161 is dictated by process capability (e.g. lithography and etching limitations).

In the ON state, the transistor 100 operates similar to a conventional LDMOS transistor. More specifically, the transistor 100 is switched ON by applying a positive voltage greater than the threshold voltage on the gate 108, creating an inversion layer or channel between the source 106 and the drift region 103. This allows electron current to flow from the source 106 through the channel, through the drift region 103, and to the drain 107. Because the gap 161 is sufficiently narrow, the gate 108 and the field plate 109 have an electric field profile similar to that of a continuous gate material, i.e., as if there is no gap 161.

In the OFF state, the voltage on the gate 108 is reduced so that there is no channel for electron current to flow. A positive drain voltage is applied relative to the source, gate, and field plate voltages, which are all substantially at the same potential. The PN junction between the P− epitaxial layer 102 and the N− drift region 103 is reverse biased, causing depletion of the drift region 103. The capacitive action of the field plate 109 and the thick gate oxide 114 further depletes the drift region 103, allowing for higher doping of the drift region 103 to advantageously reduce the ON-state resistance.

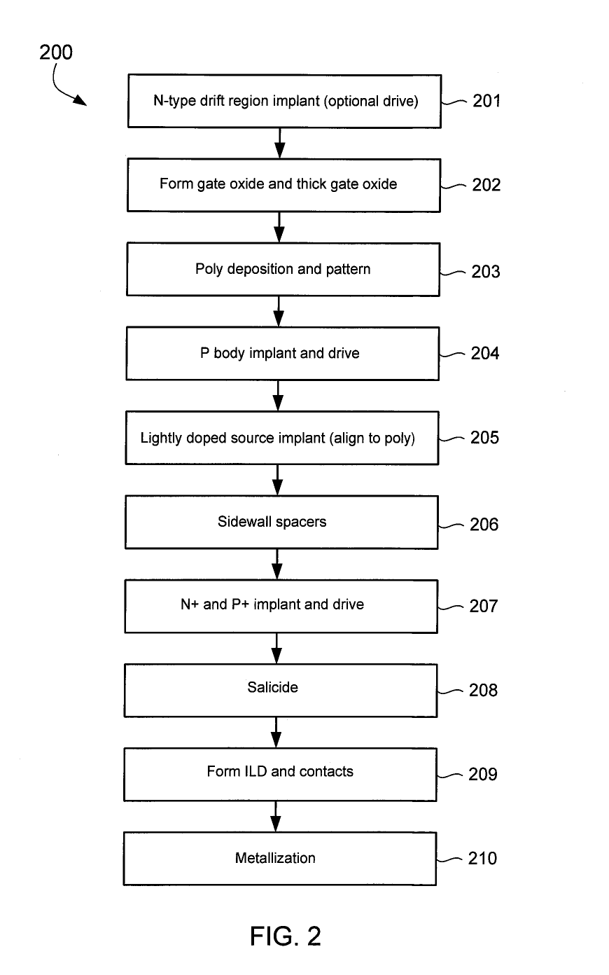

Referring now to FIG. 2, there is shown a flow diagram of a method 200 of fabricating a transistor in accordance with an embodiment of the present invention. The method 200 is explained using the lateral DMOS transistor 100 of FIG. 1 as an example.

The P− epitaxial layer 102 may be grown on the P-type substrate 101 by vapor phase epitaxy, for example. Thereafter, the N− drift region 103 is formed by implanting N-type dopants (e.g., phosphorus) into the epitaxial layer 102 (step 201). The N− drift region 103 may be formed by ion implantation and followed by a thermal drive-in step. The thermal drive-in step may be formed right after the ion implantation step or as part of another drive-in step later in the fabrication process (e.g. in step 204). For example, the drift region 103 may be formed to a depth of about 0.4 to 2 μm as measured from the top surface of the epitaxial layer 102.

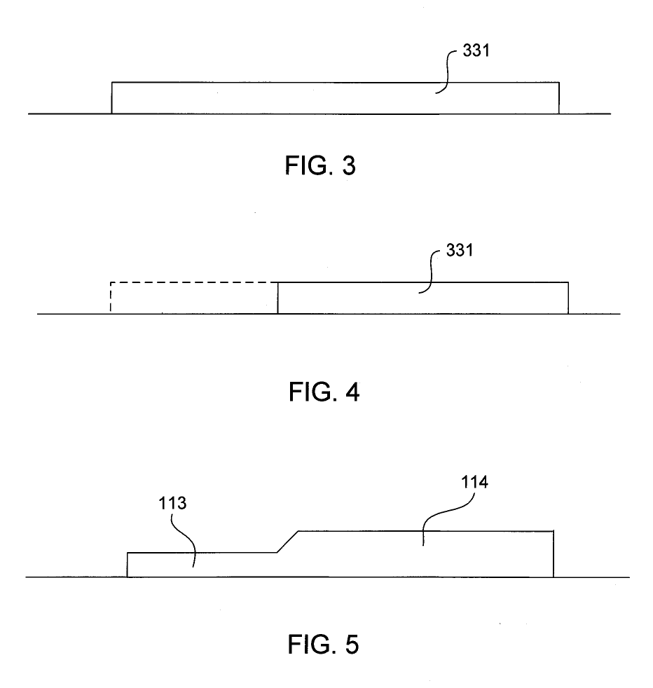

The gate oxide 113 and the thick gate oxide 114 may be formed (step 202) over the epitaxial layer 102 in a three-step process, illustrated in FIGS. 3-5. In this example where the gate dielectric comprises an oxide, an oxide layer 331 (see FIG. 3) may be thermally grown on the epitaxial layer 102, e.g., to about 200 to 800 Angstroms thick, in a first oxide formation step. In a second oxide formation step, the oxide layer 331 is patterned (see FIG. 4) by a photomask and etching process to remove portions where the gate oxide 113 will be grown (represented as dashed lines in FIG. 4). In a third oxide formation step, additional oxide is thermally grown on the epitaxial layer 102 and the remaining oxide layer 331 to create an oxide layer having a stepped profile where the gate oxide 113 is thinner than the thick gate oxide 114 (see FIG. 5; also FIG. 1). For example, about 80 to 150 Angstroms of oxide may be additionally grown in the third oxide formation step. Other steps for fabricating the gate oxide 113 and the thick gate oxide 114 may also be employed without detracting from the merits of the present invention.

The gate 108 and the field plate 109 may be formed in the same polysilicon deposition and patterning steps (step 203). For example, a layer of polysilicon (or other gate material) may be deposited on the surface of the gate oxide 113 and thick gate oxide 114. Thereafter, the layer of polysilicon may be patterned into two portions to form the separate gate 108 and field plate 109 as in FIG. 1. The layer of polysilicon may be patterned such that the gap 161 is on the thick gate oxide 114. In that example, a small portion of the gate 108 overhangs onto the thick gate oxide 114. In one embodiment, the field plate 109 is formed over the thick gate oxide but not over the gate oxide.

FIG. 6 shows a larger view of the gate 108 and field plate 109 of the transistor 100, illustrating example dimensions in accordance with an embodiment of the present invention. In the example of FIG. 6, the dimension L_{G} represents the length of the gate (e.g., 0.3 μm), dimension L_{O} represents the length of the base extension or overhang onto the thick gate oxide 114 (e.g., 0.1 μm), the dimension L_{GAP} represents the length of the gap 161 (e.g., less than 0.25 μm; 0.1 to 0.2 μm), and the dimension L_{FP} represents the length of the field plate 109 (e.g., 0.3 to 0.6 μm). These example dimensions, and all other particular dimensions disclosed herein, are for a lateral DMOS transistor having a breakdown voltage of 25V. The dimensions may be adjusted for particular breakdown voltages or fabrication processes. FIG. 6 also shows the spacers 601 and 602, which are not depicted in FIG. 1 to avoid overcrowding the figure.

The P body region 104 may be formed by ion implantation followed by a thermal drive-in step (step 204) using the gate 108 for alignment. The drive-in step drives the implanted dopants (P-type, such as boron, in this example) under the gate oxide 113 and down into the P− epitaxial layer 102. For example, the body region 104 may be formed to a depth of about 1 to 2 μm as measured from the top surface of the epitaxial layer 102.

The N− lightly doped source region 166 may be formed by ion implantation (step 205) using the gate 108 for alignment. A subsequently performed drive-in step (e.g., see step 207) drives the implanted dopants (N-type, such as phosphorus, in this example) into the P body region 104.

The sidewall spacers 110 and 111 (e.g., silicon nitride, silicon dioxide, etc.) are formed on the outer sidewalls of the gate 108 and field plate 109, respectively (step 206). The sidewall spacers are formed by conventional methods, such as deposition of a dielectric material followed by anisotropic etching. As shown in FIG. 6, sidewall spacers 601 and 602 may remain in the gap 161 when the sidewall spacers 110 and 11 are formed. That is, the gate 108 may have the spacer 110 on a sidewall and the spacer 601 on another sidewall, and the field plate 109 may have the spacer 602 on one sidewall and the spacer 111 on another sidewall. If the gap 161 is narrow enough, the gap 161 may be completely filled by the sidewall spacer dielectric material.

Thereafter, the source 106, the drain 107, and the P+ contact region 117 are formed (step 207) by ion implantation followed by a thermal drive-in step. In one embodiment, the drain 107 is formed by implanting dopants using the sidewall spacer 111 of the field plate 109 for alignment. This advantageously allows for ease of fabrication as the location of the drain 107 is not dictated by lithography. An edge of the resulting drain 107 is thus aligned with the spacer 111. In other method embodiments, the drain 107 is separated laterally from spacer 111 using a photomask.

Silicide layers 122, 112, 121, and 123 may be formed in the same self-aligned silicide (i.e. salicide) process (step 208). The ILD 105 is thereafter formed, followed by formation of contact holes (i.e., “vias”) through the ILD 105 to the source 106, the field plate 109, and the drain 107 (step 209). A metallization step forms the electrodes 115 and 116 (step 210). In the example of FIG. 1, the metallization step electrically connects the field plate 109 to the source 106. As can be appreciated, the design of the transistor 100 allows for a simplified electrical connection between the field plate 109 and the source 106. In particular, in the example of FIG. 1, the field plate 109 is electrically connected to the source 106 by way of vertical vias formed through the ILD 105. This advantageously allows the transistor 100 to be readily incorporated into an integrated circuit along with other devices.

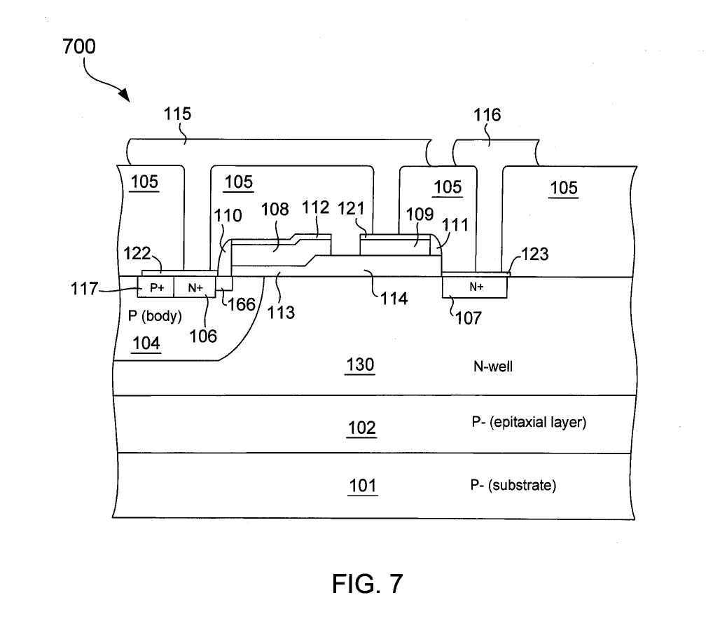

In light of the foregoing, one of ordinary skill in the art can appreciate that the transistor 100 may be modified without detracting from the merits of the present invention. As an example, FIG. 7 shows a lateral transistor in the form of a lateral DMOS transistor 700 in accordance with an embodiment of the present invention. The transistor 700 is a particular embodiment of the transistor 100 where the drain 107, the P body region 104, and all other features bounded by them are formed in an N-type well 130, such that the N-type well 130 serves as the drift region in this embodiment. All other components shown in FIG. 7 are as previously explained in connection with FIGS. 1-6.

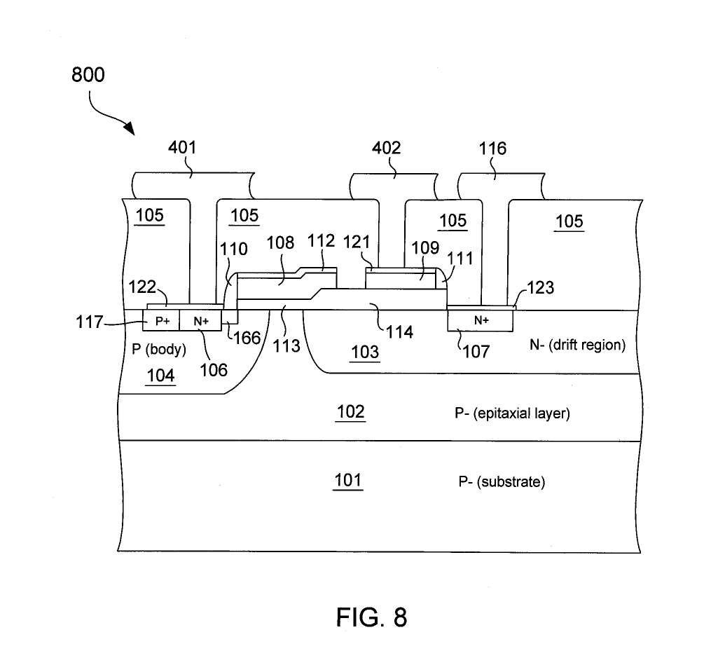

FIG. 8 shows another example of a lateral transistor in accordance with an embodiment of the present invention. In the example of FIG. 8, the lateral transistor is a lateral DMOS transistor 800. The transistor 800 is a particular embodiment of the transistor 100 where the field plate 109 is not electrically connected to the source electrode 401. In the example of FIG. 8, the field plate 109 is connected to an independent field plate electrode 402. This allows the field plate 109 to be grounded in the OFF state to deplete the N− drift region 103 using some other circuit or node, other than the source 106. For example, the field plate 109 may be electrically connected to an external or integrated electrical circuit (not shown) that can make use of the effective capacitance from the thick gate oxide 114.

Lateral transistors and method of fabricating same have been disclosed. While specific embodiments of the present invention have been provided, it is to be understood that these embodiments are for illustration purposes and not limiting. Many additional embodiments will be apparent to persons of ordinary skill in the art reading this disclosure.

1. A lateral transistor comprising:
an epitaxial layer formed over a substrate;
a source and a drain;
a gate oxide and a thick gate oxide formed over the epitaxial layer between the source and the drain, the thick gate oxide being thicker than the gate oxide;
a gate formed over the gate oxide;
a field plate formed over the thick gate oxide but not over the gate oxide;
an interlayer dielectric having a first via to the source and a second via to the field plate; and
a source electrode electrically connecting the source to the field plate by way of the first and second vias through the interlayer dielectric.

2. The transistor of claim 1 further comprising a body region surrounding the source and underlying the gate, and a drift region surrounding the drain and underlying the field plate and a portion of the gate.

3. The transistor of claim 2 wherein the body region is surrounded by the drift region.

4. The transistor of claim 2 wherein the drain region is separated laterally from the field plate by a spacer.

5. The transistor of claim 1 wherein the substrate and a body region are doped with a P-type dopant, and the source, the drift region, and the drain are doped with an N-type dopant.

6. The transistor of claim 1 wherein the transistor comprises a lateral double diffused metal-oxide-semiconductor (DMOS) transistor.

7. The transistor of claim 6 wherein the gate and the field plate are separated laterally by a gap by a distance less than 0.25 μm, the gap being filled with a dielectric material.

8. The transistor of claim 1 further comprising
a first spacer formed on a sidewall of the gate and a second spacer formed on another sidewall of the gate; and
a third spacer formed on a sidewall of the field plate and a fourth pacer formed on another sidewall of the field plate.

9. The transistor of claim 1 wherein the gate is formed over the gate oxide and a portion of the thick gate oxide.

10. (canceled)

11. (canceled)

12. (canceled)

13. (canceled)

14. (canceled)

15. (canceled)

16. (canceled)

17. A lateral transistor comprising:
a P-type semiconductor layer;
a gate formed over a gate oxide;
a field plate formed over a thick gate oxide but not over the gate oxide, the thick gate oxide being thicker than the gate oxide, the field plate being separated from the gate by a gap; and
an N+ source formed in a P-type body region and an N+ drain formed in a drift region.

18. The transistor of claim 17 further comprising:
a source electrode electrically connecting the N+ source to the field plate through a via in an interlayer dielectric.

19. The transistor of claim 17 wherein the field plate is electrically connected to the N+ source by way of a silicide layer formed on the N+ source.

20. The transistor of claim 17 wherein the N+ source is electrically connected to the field plate.
